(19) United States
(12) Patent Application Publication
(10) Pub. No.: US 2025/0173494 A1
(43) Pub. Date: May 29, 2025

(54) METHOD AND SYSTEM FOR MODELING SEMICONDUCTOR PROCESSES

(71) Applicant: Samsung Electronics Co., Ltd., Suwon-si (KR)

(72) Inventors: Hanlim CHOI, Suwon-si (KR); Hyeonkyun NOH, Suwon-si (KR); Sungwook KIM, Suwon-si (KR); Suyeon SOHN, Suwon-si (KR); Jaehoon JEONG, Suwon-si (KR); Yunji CHOI, Suwon-si (KR)

(73) Assignee: Samsung Electronics Co., Ltd., Suwon-si (KR)

(21) Appl. No.: 18/915,481

(22) Filed: Oct. 15, 2024

(30) Foreign Application Priority Data
Nov. 23, 2023 (KR) 10-2023-0164858

(51) Int. Cl. G06F 30/39; G06F 30/27

(52) U.S. Cl. CPC G06F 30/39; G06F 30/27

(57) ABSTRACT

Provided is a method of modeling a semiconductor process including obtaining a measurement value based on input data defining sub process steps and measurement steps; based on the measurement steps, grouping the sub process steps to respectively correspond to a plurality of modules; and based on the grouped sub process steps, training a machine learning model to predict at least one characteristic of a semiconductor device. The machine learning model includes a first sub model configured to output a feature value based on the plurality of modules, and based on the feature value, a second sub model configured to output an output value representing an estimated value corresponding to each of the plurality of modules and the at least one characteristic of the semiconductor device.

### CROSS-REFERENCE TO RELATED APPLICATION

This application is based on and claims ranking under 35 U.S.C. § 119 to Korean Patent Application No. 10-2023-0164858, filed on Nov. 23, 2023 in the Korean Intellectual Property office, the disclosure of which are incorporated by reference herein in its entirety.

### BACKGROUND

Various example embodiments relate to a method and/or a system for modeling a semiconductor process, and more particularly, to a method and/or a system for modeling a semiconductor process by using learning such as machine learning.

Predicting the result by analyzing a semiconductor process in advance may improve the reliability of the characteristics of the semiconductor devices and/or may shorten the period of developing and researching the semiconductor devices. Such prediction may, in general, be referred to as technology-based computer aided design (TCAD).

However, with the recent advancement of semiconductor technology and increased integration, estimating and interpreting the process and results thereof in advance considering various conditions/factors of processes may require high costs, such as time and/or computing resources. Accordingly, there is an increasing need or desire for technology for accurately modeling a semiconductor process while providing improved explanatory properties.

### SUMMARY

Various example embodiments provide a method and/or a system for modeling a semiconductor process, which may more accurately and/or efficiently perform modeling of the semiconductor process, and/or may provide improved explanatory properties and/or higher quality analysis.

According to some example embodiments, there is provided a method of modeling a semiconductor process including obtaining a measurement value based on input data defining sub process steps and measurement steps; based on the measurement steps, grouping the sub process steps to respectively correspond to a plurality of modules; and based on the grouped sub process steps, training a machine learning model to predict characteristics of a semiconductor device. The machine learning model includes a first sub model configured to output at least one feature value based on the plurality of modules, and based on the feature value, a second sub model configured to output an output value representing an estimated value corresponding to each of the plurality of modules and the characteristics of the semiconductor device.

Alternatively or additionally, there is provided a method of modeling a semiconductor process including receiving input data defining sub process steps and measurement steps; based on the measurement steps, grouping the sub process steps to correspond to a plurality of modules; computing at least one feature value corresponding to each of the sub process steps; by using a sub model, outputting an estimated value corresponding to each of the plurality of modules based on the feature value, by using the sub model, outputting an output value representing at least one characteristic of a semiconductor device based on the feature value; and based on at least one of the estimated value and the output value, training the sub model.

Alternatively or additionally according to various example embodiments, there is provided a system for modeling a semiconductor process including at least one processor configured to execute machine-readable instructions that, when executed by the at least one processor, cause the system receive input data defining sub process steps and measurement steps and provide a machine learning model, the machine learning model configured to predict characteristics of a semiconductor device based on the input data, wherein the machine learning model computes a feature value corresponding to each of the sub process steps, and based on the feature value, outputs a first output value predicting at least one characteristic of a semiconductor device and a second output value predicting an amount of change of the at least one characteristic of the semiconductor device according to change of physical characteristic.

### BRIEF DESCRIPTION OF THE DRAWINGS

Embodiments will be more clearly understood from the following detailed description taken in conjunction with the accompanying drawings in which:

FIG. 1 is a diagram of a modeling process according to some example embodiments;

FIG. 2 is a block diagram of a structure of a machine learning model according to some example embodiments;

FIG. 3 is a diagram of a modeling process according to some example embodiments;

FIG. 4 is a diagram of grouping according to some example embodiments;

FIG. 5 is a diagram of a filtering process according to some example embodiments;

FIG. 6 is a diagram of feature value calculation according to some example embodiments;

FIG. 7 is a diagram of feature map generation according to some example embodiments;

FIG. 8 is a diagram of feature map analysis according to some example embodiments;

FIG. 9 is a diagram of loss terms based on estimation values according to some example embodiments;

FIG. 10 is a diagram of a method of predicting features of a semiconductor device, according to some example embodiments;

FIG. 11 is a diagram of loss terms based on output values according to some example embodiments;

FIG. 12 is a diagram of an example of utilizing a loss term, according to some example embodiments;

FIG. 13 is a flowchart of a modeling method according to some example embodiments;

FIG. 14 is a flowchart of a feature value calculation method according to some example embodiments;

FIG. 15 is a flowchart of a training method according to some example embodiments;

FIG. 16 is a flowchart of a training method according to some example embodiments;

FIG. 17 is a block diagram of a process of providing a machine learning model, according to some example embodiments; and

FIG. 18 is a block diagram of a modeling system according to some example embodiments.

### DETAILED DESCRIPTION OF VARIOUS EXAMPLE EMBODIMENTS

Hereinafter, various example embodiments will be described in detail with reference to the accompanying drawings.

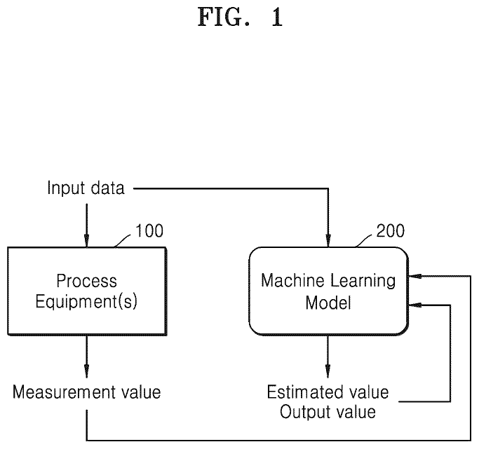

FIG. 1 is a diagram of a modeling process according to some example embodiments.

Referring to FIG. 1, a machine learning model 200 for modeling a semiconductor process may receive input data and may output an output value indicating an estimated value and/or a feature of a semiconductor device, and may receive at least one actual measurement value obtained by at least one process equipment(s) 100 and/or a measurement value obtained from database.

In some example embodiments, the machine learning model 200 may include an artificial neural network (ANN) to model a semiconductor process. The ANN may be referred to as and/or may include various computing systems conceived from a biological neural network constituting an animal brain. As an example, the machine learning model 200 may include a convolutional neural network (CNN). However, the ANN included in the machine learning model 200 is not limited thereto and may be variously implemented. For example, the machine learning model 200 may alternatively or additionally include a recurrent neural network (RNN). For example, the machine learning model 200 may be implemented based on one or more of a long short-term memory (LSTM) technique, a Gated Recurrent Unit (GRU) technique, an attention technique, etc. Unlike classical algorithms that perform tasks according to pre-defined conditions such as rule-based programming, the ANN may learn to perform tasks by considering multiple samples (or examples), for example, multiple pieces of input data. The ANN may have a structure in which artificial neurons (or neurons) are connected to each other and connections between the neurons may be referred to as synapses. The neurons may process the received signals and transmit the processed signals to other neurons via synapses. The output of the neuron may be referred to as activation. The neuron and/or synapse may have a variable weight, and an influence of the signal processed by the neuron may increase or decrease according to the weight. In particular, the weight associated with each neuron may be referred to as a bias.

However, the machine learning model 200 may be implemented based on various learning methods and/or algorithms without being limited to the ANN with respect to machine learning methods for modeling a semiconductor process. For example, the machine learning model 200 may also or alternatively be implemented based on a random forest technique.

Input data may include data defining sub process steps (hereinafter, referred to as process steps), as well as measurement steps. Sub process steps may be referred to as process steps for manufacturing a semiconductor device. For example, sub process steps may indicate a photolithography process, an etching process, an ion implantation process such as a beamline implantation and/or a plasma doping implantation, a planarization process such as a chemical mechanical polishing (CMP) process, a wet processing step, a deposition process such as a chemical vapor deposition process, an annealing process such as a laser annealing process, a baking process, etc. Measurement steps may refer to operations to verify whether one or more sub process steps have been properly performed. For example, measurement steps may be operations of testing structural and/or electrical characteristics of a semiconductor device after a series of sub process steps have been performed, and in some cases may include one or more of a critical dimension (CD) measurement, a scribe-line test measurement, an ellipsometry measurement, a film thickness measurement, etc.

The process equipment(s) 100 may receive input data and output a measurement value Mv as the result of actually performing a process. For example, the measurement value Mv may be or may include or indicate a value of a threshold voltage and/or the (signed or unsigned) magnitude of a current of the manufactured semiconductor device, and/or a resistance such as a sheet resistance of a layer of the semiconductor device and/or a contact resistance and/or via resistance of a contact and/or a via of the semiconductor device. However, the measurement value Mv is not limited thereto and may include various values indicating the characteristics of the semiconductor device. On the other hand, the measurement value Mv may also indicate data in which numerous actual results of previous processes are stored. For example, the measurement value Mv may indicate historical data obtained from a database (for example, a domain knowledge database) in which the actual process results are recorded.

The machine learning model 200 may receive the input data and output an estimated value as described below. The estimated value may indicate a value which predicts the result of the measurement steps. For example, the estimated value may be or may include a value corresponding to the result of a series of sub process steps. The machine learning model 200 may output an output value for predicting the characteristics of the semiconductor device. The output value may include a value which predicts characteristics (for example, electrical and/or physical characteristics such as a threshold voltage) of a semiconductor device to be manufactured by sub process steps of the input data. On the other hand, the output value may include a value for predicting a change in the characteristics of the semiconductor device according to the change in the physical characteristics of the semiconductor processes. For example, when some conditions of the sub process steps (for example, doping concentration) change, the output value may be a value which predicts the characteristics of the semiconductor device (for example, a change in the threshold voltage) accordingly. The modeling method according to some example embodiments may model a semiconductor process through training of the machine learning model 200, based on the estimated value, the output value, and the measurement value Mv described above.

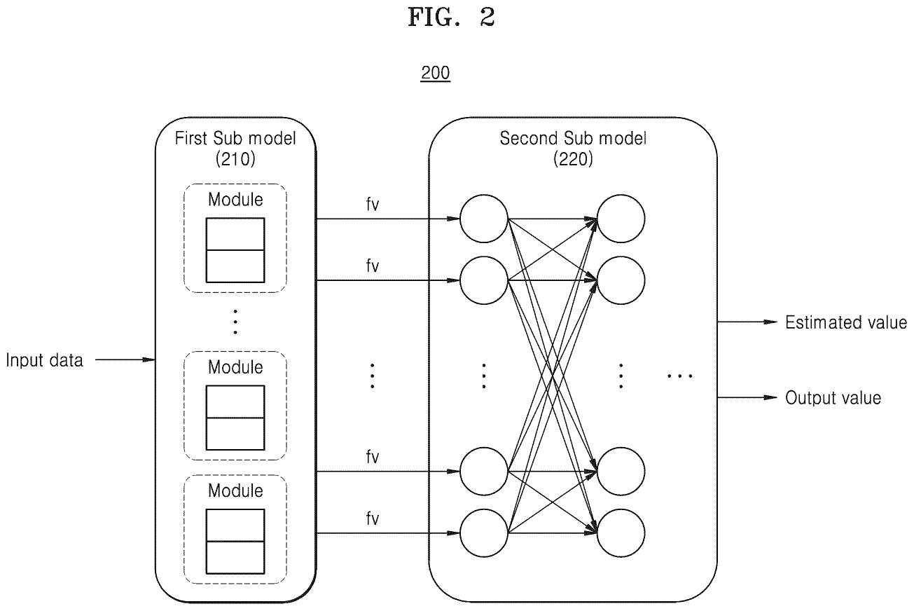

FIG. 2 is a block diagram of a structure of the machine learning model 200 according to some example embodiments.

Referring to FIG. 2, the machine learning model 200 may include a first sub model 210 and a second sub model 220. The input data may be grouped (or divided or partitioned), and the machine learning model 200 may output the estimated value and the output value as described above based on the grouped input data.

The first sub model 210 may include a plurality of modules. Each of the plurality of modules may be referred to as a unit and/or a block in which at least one function is performed and may correspond to, for example, a unit in which a series of computation processes occur. The input data may be grouped to correspond to a plurality of modules of the first sub model 210. The input data may include data defining sub process steps and measurement steps, and the sub process steps may be grouped (or divided or partitioned) based on the measurement steps. For example, each module may include one or more sub process steps.

The first sub model 210 may receive data on sub process steps grouped to correspond to a plurality of modules. The first sub model 210 may represent data for sub process steps as a specific value so that sub process steps corresponding to each of the plurality of modules may be processed by the machine learning model 200. In some example embodiments, the first sub model 210 may filter data for sub process steps and represent the filtered data as a feature value fv. For example, each feature value fv may be or may be based on a value corresponding to each of the sub process steps.

The second sub model 220 may perform various computations based on the feature values fv, and as a result, may output the estimated value and/or the output value. In some example embodiments, the second sub model 220 may perform a computation operation on the feature values fv based on an ANN. The second sub model 220 may output the estimated value for predicting a result of sub process steps corresponding to each module. For example, each estimated value may be a value corresponding to each of the modules.

However, the machine learning model 200 is not limited to the above, and may further include other sub model(s) for performing multiple functions. The first sub model 210 and/or the second sub model 220 may also include lower sub model(s) therein.

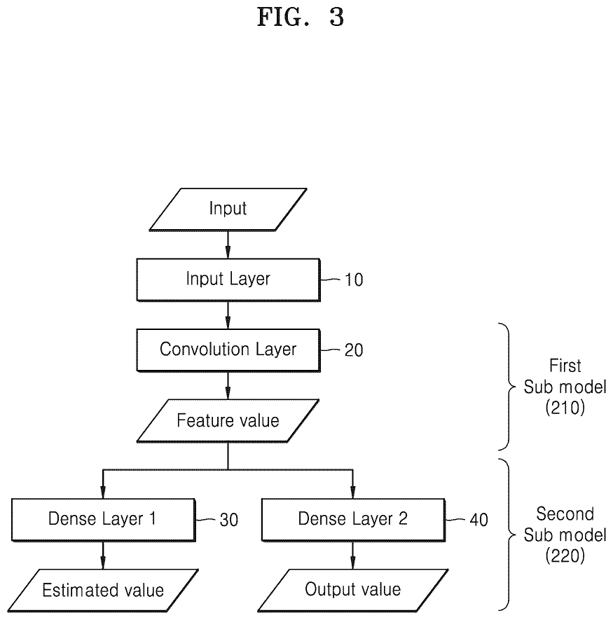

FIG. 3 is a diagram of a modeling process according to some example embodiments.

Referring to FIG. 3, an input layer 10 may receive input data Input. The input data Input may be or may include data defining sub process steps and measurement steps, and as the input data Input is received via the input layer 10, the sub process steps included in the input data Input may be grouped based on the measurement steps.

In some example embodiments, the first sub model 210 may include a convolution layer 20. The first sub model 210 may input the grouped sub process steps to the convolution layer 20 for a certain filtering process. The first sub model 210 may express each of the sub process steps as a particular value by passing each of the sub process steps through the convolution layer 20, for example, a kind of filter, as to be described below. Data for each of the sub process steps may be output as one or more feature values fv by passing through the convolution layer 20, and as a result, sequentiality between the sub process steps may also be reflected or maintained.

In some example embodiments, the second sub model 220 may include a first dense layer 30 and/or a second dense layer 40. The second sub model 220 may receive the feature value fv and may input the received feature value fv to the first dense layer 30. The second sub model 220 may output the estimated value corresponding to the grouped sub process steps, by performing a certain computation operation based on the feature value fv by using the first dense layer 30. In addition, the second sub model 220 may output the output value, which predicts one or more characteristics of the semiconductor device, and/or an output value, which predicts a change in the one or more characteristics of the semiconductor device according to a change in physical characteristics of the semiconductor device, by performing a certain computation operation based on the feature value fv by using the second dense layer 40.

However, the first sub model 210 and the second sub model 220 are not limited to the above and may alternatively or additionally include other layer(s) than the illustrated layers for performing various operation(s).

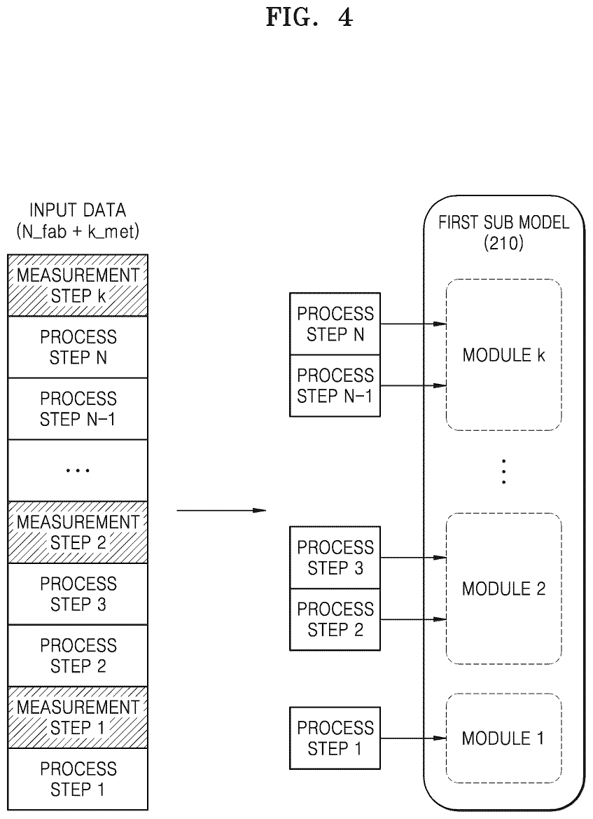

FIG. 4 is a diagram of grouping according to some example embodiments.

Referring to FIG. 4, the input data may be grouped to correspond to the plurality of modules of the first sub model 210. The input data may include data defining N sub process steps and k measurement steps (N and k are natural numbers of 2 or more). For example, a first measurement step may be performed after a first process step, and a second measurement step may be performed after second and third process steps. In a similar manner, a k^{th} measurement step may be performed after (N-1)^{th} and N^{th} process steps. In this case, the input data may be grouped based on the measurement steps. In some example embodiments, more than one measurement step may be performed in succession after one or more process steps; example embodiments are not limited thereto. In some example embodiments, the process steps performed between the measurement steps may be grouped into one group, and the group may be provided as an input of a corresponding module. For example, each of the plurality of modules may receive data for one or more process steps grouped based on the criteria described above. For example, data for the first process step may be provided to a first module, data on the second and third process steps may be provided to a second module, and data on the (N-1)^{th} and N^{th} process steps may be provided to the k^{th} module. Because the process steps are divided based on the measurement steps and provided to the module, the plurality of modules may respectively correspond to the measurement steps.

In the modeling method according to various example embodiments, inputs to a machine learning model may include only process steps, by distinguishing between measurement steps and process steps by using modularization. For example, because the performance result of the measurement steps is simply a result of some process steps, by separating the performance result from the process steps into a different level, a modeling conforming with the real world, e.g., a modeling with better consistency, may be possible, and/or an unnecessary amount of computations may be reduced.

Alternatively or additionally, by separating the measurement steps, the modularization of the modeling method according to various example embodiment may prevent or reduce the likelihood that the number of data sets from decreasing due to missing measurement during the measurement steps in an actual process. For example, when measurement steps are also input to the model, because data does not exist for the portion where the missing measurement occurs, learning may become impossible and/or inaccurate, and accordingly, one or more of poor utilization of data, low consistency, or difficulty in deriving accurate features and results may occur. On the other hand, in the modeling method according to various example embodiments, even when the missing measurement occurs, because learning is performed for each module, tolerance against the missing measurement may be increased, and by sufficiently utilizing input data sets, it may be possible to increase consistency and/or more accurately identify desired features.

Alternatively or additionally, because the modeling method according to various example embodiments may compute the estimated value for each module separated as such, learning close to the actual measurement value for each module may be possible, the accuracy of the modeling may be further improved, and/or more improved or optimized process conditions may be suggested.

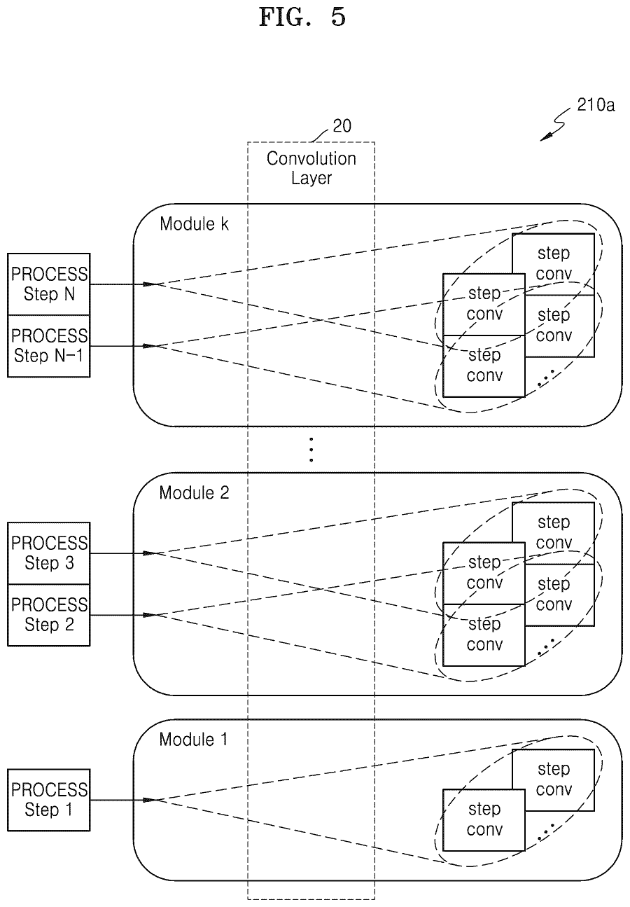

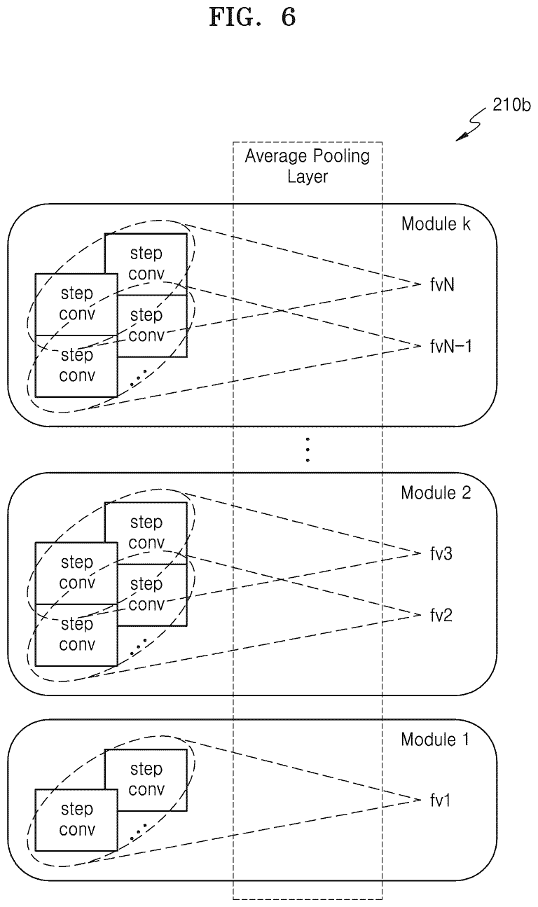

FIG. 5 is a diagram of a filtering process according to some example embodiments. FIG. 6 is a diagram of feature value fv computation according to some example embodiments.

Referring to FIG. 5, a first sub model 210a may include the convolution layer 20. The first sub model 210a may correspond to the first sub model 210 in FIG. 2, and may be or may include or be included in an implementation of the first sub model 210. The first sub model 210a may receive data that has undergone the grouping process described with reference to FIG. 4. For example, the first sub model 210a may receive data grouped to correspond to each of the k modules, and each module may perform a convolutional multiplication computation by using the convolution layer 20. For example, the first sub model 210a may perform a kind of filtering operation. Data for each process step included in the module may be expressed as various convolutional multiplication result value steps conv by using the filtering process. For example, the convolutional multiplication computation may be or may include a one-dimensional (1D) convolution.

Referring to FIG. 6, a first sub model 210b may output feature values fv based on the convolutional multiplication result values step conv. The first sub model 210b may correspond to the first sub model 210 in FIG. 2, and may be an implementation. As a result of performing the convolutional multiplication computation on any one process step, a plurality of convolutional multiplication result values step conv may be generated, and the first sub model 210b may output the feature value fv corresponding to the any one process step, based on a computation using the convolutional multiplication result values step conv result values step conv. In some example embodiments, the first sub model 210b may include an average pooling layer performing an average value computation. For example, the average may be or be based on one or more measures of central tendency, such as but not limited to one or more of a mean, a median, or a mode. Each of the modules may perform an average computation by using the average pooling layer. As a result, the first sub model 210b may output an average of the result values sept conv as the feature value fv by performing an average pooling operation. For example, the first module may output a first feature value fv1 as a value corresponding to the first process step (or indicating the first process step); the second module may output a second feature value fv2 as a value corresponding to a second process step; and a third feature value fv3 as a value corresponding to a third process step; and in the same manner, the k^{th} module may output an (N-1)^{th} feature value fvN−1 as a value corresponding to an (N-1)^{th} process step; and an N^{th} feature value fvN as a value corresponding to an N^{th} process step. For example, the feature value fv corresponding to each of the process steps may have a value between about −1 and about 1. However, such operations and/or calculations are not limited to the above, and other computation operations may additionally or alternatively be performed to output the feature value fv. For example, a max pooling operation may also be performed on the result values step conv.

The modeling method according to various example embodiments may reflect the sequentiality of process steps included in a module by using a certain filtering operation, and may be expressed as a feature value fv reflecting the feature/characteristics of each of the process steps. Alternatively or additionally, the modeling method according to the embodiment may further improve the explanatory properties of a model because it is possible to understand how a model interprets the input (process steps) by using the feature values fv.

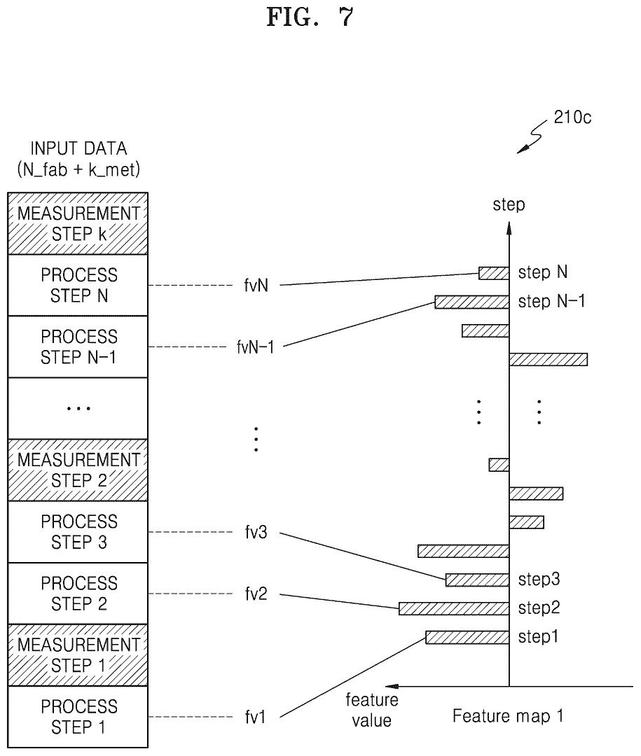

FIG. 7 is a diagram of feature map generation according to some example embodiments.

Referring to FIG. 7, a first sub model 210c may generate a first feature map based on the plurality of feature values fv1 to fvN. The first sub model 210c may correspond to the first sub model 210 in FIG. 2, and may be an implementation thereof. As described with reference to FIGS. 5 and 6, data for the grouped process steps may be expressed as feature values fv by using the filtering process. For example, the process steps defined in the input data may include the first process step, the second process step, the third process step, . . . , the (N-1)^{th} process step, and the N^{th} process step (N is a natural number of 2 or more). After a certain filtering process is completed, the first process step may be expressed as the first feature value fv1, the second process step may be expressed as the second feature value fv2, the third process step may be expressed as the third feature value fv3, the (N-1)^{th} process step may be expressed as the (N-1)^{th} feature value fvN−1, and the N^{th} process step may be expressed as the N^{th} feature value fvN. The first sub model 210c may generate the first feature map by using the plurality of feature values fv1 to fvN. The first feature map may be expressed, for example, in the form of a graph in which each of the process steps is matched to a feature value corresponding thereto.

Because the modeling method according to various example embodiments may identify how the characteristics of an individual process step are reflected as values through the feature map, the relationship between which process steps affect which characteristics of the semiconductor device may be identified, and the explanatory properties of the model may be further improved.

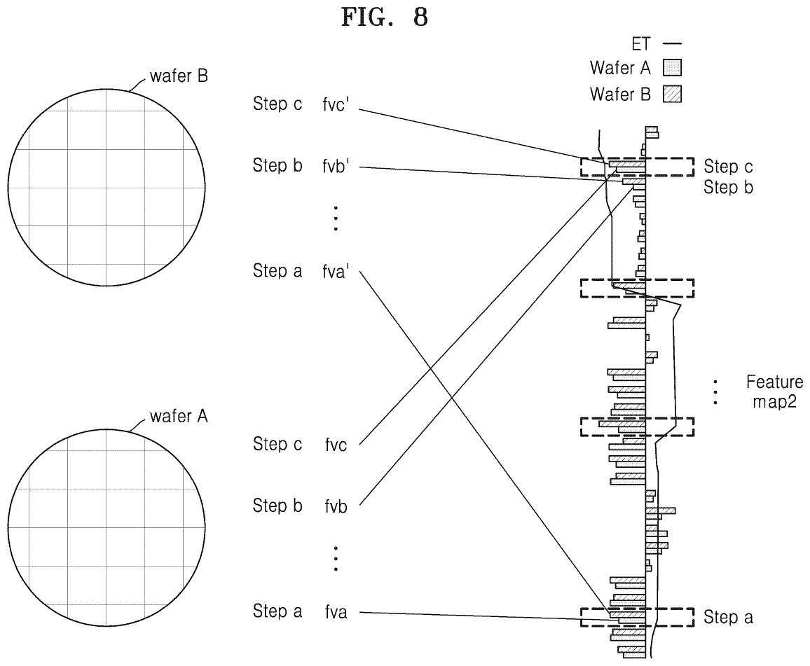

FIG. 8 is a diagram of an example of analyzing the feature map, according to some example embodiments.

Referring to FIGS. 7 and 8, the first sub model 210c may generate a second feature map in which two or more pieces of input data are modeled and compared with each other. For example, the first sub model 210c may output feature values fva to fvc indicating data for each of the process steps (steps a to c) corresponding to the manufacturing of a substrate such as wafer A and may display the feature values fva to fvc as a graph on the second feature map. In the same manner, the first sub model 210c may output feature values fva′ to fvc′ indicating data for each of the process steps (steps a to c) corresponding to the manufacturing of a substrate such as wafer B and may display the feature values fva′ to fvc′ as a graph on the second feature map. The global process for manufacturing wafers A and B, for example, the processes of steps a to c, may be the same, but the detailed process conditions of each of the steps may be different. For example, there may be an in-silico experimental design between the processing of wafer A and wafer B. For example, when the process conditions of process step a of manufacturing the wafer A is different than process step a of manufacturing the wafer B (for example, when the doping concentrations are different during one or more doping processes), the feature value fva may be different from the feature value fva′. Likewise, feature values corresponding to each process step of each wafer may variously change.

The first sub model 210c may represent the feature values fva to fvc for process steps of the wafer A and the feature values fva to fvc for process steps of the wafer B, in the second feature map, and may represent a graph for various electrical characteristics ET comparing the electrical characteristics of the wafer A to the electrical characteristics of the wafer B, in the second feature map. For example, electrical characteristics ET may indicate information about one or more threshold voltages such as the threshold voltages of various transistors, such as thin-gate and/or thick-gate transistors, and the difference between the threshold voltages of particular transistors of wafer A and wafer B may be illustrated as a line graph (ET graph). The correlation between the difference in feature values for each process step of two wafers and the graph of the change in the electrical characteristics ET may be identified. For example, as illustrated, it may be understood that the change in the electrical characteristics ET is relatively large in steps where the difference in feature values between process steps is relatively large.

In some example embodiments, by analyzing the correlation by using the feature map, e.g., by identifying a portion where the change in the electrical characteristics ET is significant, the modeling method may also identify the differences in the impact on electrical performance from process steps between an N-channel field effect transistor (FET) (NFET) and a P-channel FET (PFET) process and/or between a thin-gate and a thick-gate process, for example, the process steps related to the photo mask operation and/or annealing processes.

As described above, the modeling method according to some example embodiments may generate the feature map based on the feature values for each of different pieces of input data, and by illustrating the change in the electrical characteristics in the feature map, may provide information for identifying a correlation by comparing the difference between the process steps and the change in the electrical characteristics.

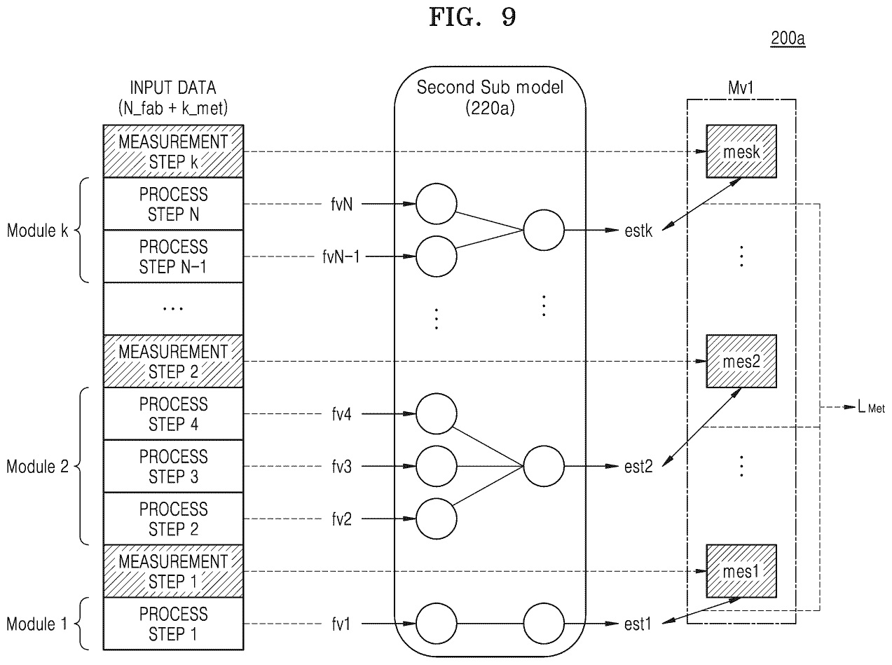

FIG. 9 is a diagram of loss terms based on estimation values according to some example embodiments.

Referring to FIG. 9, a second sub model 220a may receive the feature values fv1 to fvN respectively corresponding to the process steps and output estimated values est1 to estk. The second sub model 220a may be a model corresponding to the second sub model 220 in FIG. 2. As described above, the input data defining N process steps and k measurement steps may be grouped to correspond to k modules based on the measurement steps. As described above, data for grouped process steps, that is provided to the plurality of modules, (for example, the first process step provided to the first module, the second to fourth process steps provided to the second module, and the (N-1)^{th} and N^{th} process steps provided to the k^{th} module), may be expressed as the feature values fv1 to fvN after the filtering operation.

In some example embodiments, the second sub model 220a may perform a certain operation in units of modules based on the received the feature values fv1 to fvN. Accordingly, the second sub model 220a may output estimated values est1 to estk respectively corresponding to each of the modules as the result of computation. In other words, the second sub model 220a may output estimated values est1 to estk respectively corresponding to the measurement steps (first to k^{th} measurement steps). The estimated value may mean a value that predicts a result value of each of the measurement steps as described above, that is, a value that predicts a result of sub process steps corresponding to each module. For example, the second sub model 220a may output the first estimated value est1 corresponding to the first module (that is, predicting the result of process step(s) included in the first module), a second estimated value est2 corresponding to the second module (that is, predicting the result of the second to fourth process steps), and a k^{th} estimated value estk corresponding to the k^{th} module. On the other hand, for example, the second sub model 220a may include a first fully connected layer (for example, the first dense layer 30 in FIG. 3) performing the computation described above. The first fully connected layer may receive feature values fv1 to fvN via N nodes and output estimated values est1 to estk via k nodes.

In some example embodiments, a machine learning model 200a may compare estimated values est1 to estk with a first measurement value Mv1. The machine learning model 200a may correspond to the machine learning model 200 in FIGS. 1 and 2, and may be an implementation thereof. The first measurement value Mv1 may include first to k^{th} actual measurement values mes1 to mesk, which are measured results of each of the measurement steps. For example, because the process steps are divided into k modules based on the measurement steps, the second sub model 220a may output k estimated values (first to k^{th} estimated values est1 to estk), and the machine learning model 200a may obtain (or receive) the first measurement value Mv1 from the outside, including k measurement values (first to k^{th} actual measurement values mes1 to mesk), which are the actual measurement results of each of the k measurement steps.

The machine learning model 200a may compare estimated values est1 to estk, which are the predicted values of the model, with the first measurement value Mv1, which is an actual measurement value. For example, the machine learning model 200a may compute the difference between the first estimated value est1 and the first actual measurement value mes1, and in the same manner, each difference, such as the difference between the second estimated value est2 and the second actual measurement value mes2, and the difference between the k^{th} estimated value estk and the k^{th} actual measurement value mesk may be computed. The machine learning model 200a may compute a first loss L_{Met} in which all of the differences is added. The machine learning model 200a may be trained so that the estimated values est1 to estk approach the first measurement value Mv1 by using the first loss LMet as inputs of various loss functions. For example, the machine learning model 200a may adjust weights and/or biases between nodes of the first fully connected layer in the second sub model 220a.

In some example embodiments, some of the k measurement steps may not be measured. In other words, some of the first measurement value Mv1 and some of the first to k^{th} actual measurement values mes1 to mesk may not have values due to the missing measurement. Accordingly, the machine learning model 200a may not be trained with respect to portions with the missing measurement. However, because the machine learning model 200a is divided into modules and trained, learning may proceed for the portions where there are actual measurement values, and thus, even when there is a portion where the measurement is missing, the data may be accumulated and accurate prediction may be performed as the training proceeds. In other words, even when there is missing measurement, the machine learning model 200a may proceed training without loss of data parameters, and thus the consistency and accuracy of the machine learning model 200a may be improved. Furthermore, because machine learning model 200a is divided into modules and trained for each module, prediction and verification for each module may be possible, sophisticated analysis may be possible, and the explanatory properties of the machine learning model 200a may be further improved.

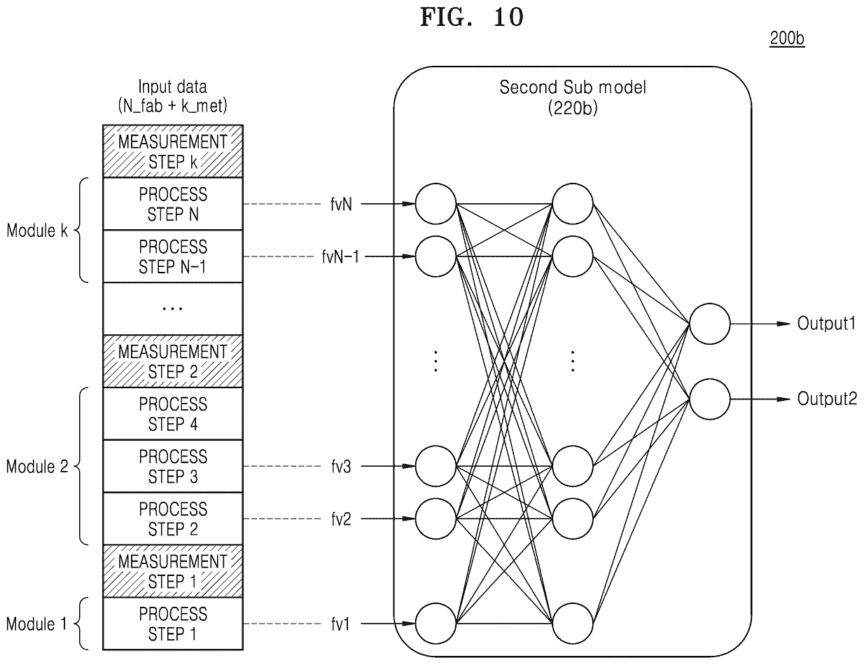

FIG. 10 is a diagram of a method of predicting characteristics of a semiconductor device 200b, according to some example embodiments.

Referring to FIG. 10, a second sub model 220b may receive the feature values fv1 to fvN corresponding to each of the process steps and output a first output value output1 and a second output value output2. The second sub model 220b may correspond to the second sub model 220 in FIG. 2 and may be an implementation thereof. The first output value output1 may be a value for predicting the characteristics of a semiconductor device, and may be, for example, a value for predicting the characteristics (for example, a threshold voltage) of a semiconductor device to be manufactured by process steps (first to N^{th} process steps) of the input data. The second output value output2 may be a value for predicting a change in characteristics of a semiconductor device according to a change in physical characteristics. For example, when the conditions (for example, doping concentration) of some of the process steps (for example, doping process) among the process steps (the first process step to N^{th} process step) are changed, the second output value output2 may be a value that predicts the characteristics of the semiconductor device (for example, a change in the threshold voltage). However, the change in the characteristics of the semiconductor device according to the change in the physical characteristics may not be limited to the change in the threshold voltage according to the doping concentration but may further include various physical characteristics. For example, the physical characteristics of the semiconductor processes may include characteristics/conditions related to a structure, and/or characteristics/conditions related to pressure, etc. For example, a machine learning model 200b may output the second output value output2 to identify a change in the threshold voltage according to a change in the gate length of a transistor and/or a change in warpage according to a change in pressure. The machine learning model 200b may correspond to the machine learning model 200 in FIGS. 1 and 2, and may be an implementation thereof.

On the other hand, for example, the second sub model 220b may include a second fully connected layer (for example, the second dense layer 40 in FIG. 3) which performs a computation for outputting the first output value output1 and the second output value output2. The second fully connected layer may receive the feature values fv1 to fvN via N nodes, and output the first output value output1 and the second output value output2.

In some example embodiments, the first output value output1 and/or the second output value output2 may include a plurality of predicted values. For example, the first output value output1 may include values that predict various characteristics of the semiconductor device, and the second output value output2 may include values that predict change in various characteristics of the semiconductor device according to change in the physical characteristics. In other words, the output of the second fully connected layer may not be limited to two nodes, and may be variously adjusted according to the target characteristics or the number of changes in the characteristics.

The modeling method according to various example embodiments may predict the change in the characteristics of the semiconductor device according to the change in various physical characteristics as well as the change in the characteristics of the semiconductor device according to process steps. Furthermore, the modeling method according to various example embodiments may predict and interpret the actual results of the manufacturing process by reflecting the change in various physical characteristics in real time, and may thus improve the accuracy of modeling and provide a powerful analysis tool.

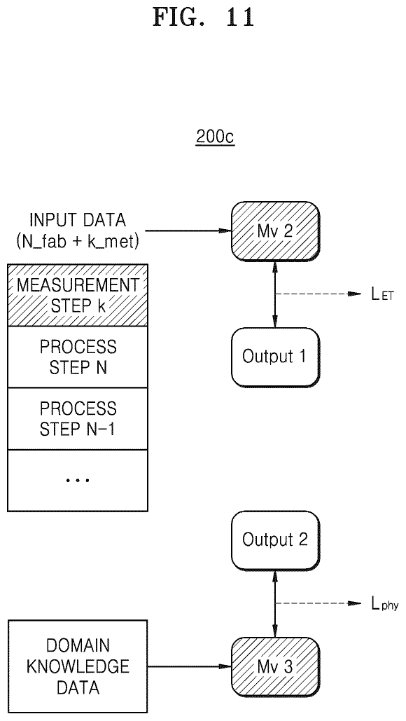

FIG. 11 is a diagram of loss terms based on output values according to some example embodiments.

Referring to FIGS. 10 and 11, a machine learning model 200c may respectively compare the first output value output1 and the second output value output2, which are predicted values thereof, to a second measurement value Mv2 and a third measurement value Mv3, which are actual measurement values. The machine learning model 200c may correspond to the machine learning model 200 in FIGS. 1 and 2, and may be an implementation thereof. The second measurement value Mv2 may be a value indicating the characteristics of the semiconductor device on which processes have actually been performed according to process steps (the first to N^{th} process steps) defined in the input data. For example, the second measurement value Mv2 may be the actual measurement value of the characteristics (for example, threshold voltage) of the semiconductor device manufactured by using the process steps (the first to N^{th} process steps) of the input data. The third measurement value Mv3 may be a value obtained by actually measuring change in characteristics of the semiconductor device according to change in the physical characteristics (for example, doping concentration, structure, pressure, etc.) of the semiconductor processes. For example, the third measurement value Mv3 may be a database of the semiconductor device processes, that is, data obtained empirically from numerous accumulated processes. In an example, the machine learning model 200c may acquire (or receive), as the third measurement value Mv3, a change value in the characteristics of the semiconductor device corresponding to a change in the physical characteristics of the target (or arbitrarily set) from a database synthesizing numerous semiconductor process results (i.e., from domain knowledge data) as a third measurement value Mv3.

In some example embodiments, the machine learning model 200c may compare the first output value output1, which is a predicted value thereof, with the second measurement value Mv2 corresponding to the first output value output1. For example, the machine learning model 200c may compute the difference between the first output value output1 and the second measurement value Mv2. When the first output value output1 includes a plurality of predicted values, the machine learning model 200c may compute a second loss LET obtained by summing the differences between the actual measurement values corresponding to each of the predicted values. In the same manner, the machine learning model 200c may compare the second output value output2, which is the predicted value thereof, with the third measurement value Mv3 corresponding to the second output value output2, and when the second output value output2 includes a plurality of predicted values, the machine learning model 200c may compute a third loss L_{Phy} obtained by summing the differences between the actual measurement values (that is, obtained from the database) corresponding to each of the predicted values. The machine learning model 200c may be trained such that the first and second output values output1 and output2 approach the second and third measurement values Mv2 and Mv3 by using the second loss L_{ET} and/or the third loss L_{Phy} as an input of various loss functions. For example, the machine learning model 200c may adjust weights and/or biases between nodes of the second fully connected layer in the second sub model 220b.

In this manner, the modeling method according to various example embodiments may learn and predict not only the actual results of the manufacturing process but change in the characteristics of the semiconductor devices according to change in various physical characteristics/conditions of the semiconductor processes. For example, in the modeling method according to various example embodiments, because the model not only learns data mathematically but reflects various physical characteristics in the modeling in real time, the accuracy of the model may be improved and analytic capability in predicting the model may also be reinforced.

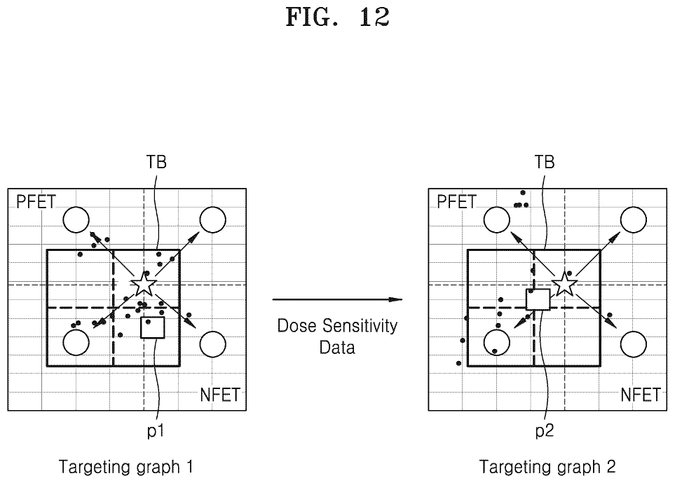

FIG. 12 is a diagram of an example of utilizing a loss term, according to some example embodiments.

Referring to FIGS. 11 and 12, the machine learning model 200c may reflect the physical characteristics and/or the electrical characteristics of a semiconductor device in the model based on domain knowledge data. For example, the result of measuring the characteristics of a semiconductor device, which is manufactured based on arbitrary input data, may be represented as a first targeting graph targeting graph 1. Results for a plurality of wafers included in one lot may be represented on a targeting graph as illustrated. The x-axis of the targeting graph may represent a value indicating at least one physical or electrical characteristic of the NFET, and the y-axis may represent a value indicating at least one physical or electrical characteristic of the PFET. For example, the x-axis of the targeting graph may indicate the threshold voltage value of a particular NFET included in a semiconductor device, and the y-axis of the targeting graph may indicate the threshold voltage value of a particular PFET included in a semiconductor device. To achieve or acceptably perform according to the target characteristics (product characteristics or target specifications), the characteristics of a semiconductor device manufactured by using the process steps may be required to satisfy the specifications corresponding to the center (bold dotted center) of a targeting box TB. As illustrated in the first targeting graph targeting graph 1, the specification of a semiconductor device manufactured based on the input data may be represented by a first point p1. For example, the actual specification may not satisfy the target specification.

In some example embodiments, the machine learning model 200c may utilize, to reflect a change in the physical characteristics of a semiconductor processes, a database (for example, domain knowledge data) related to the process described above. For example, dose or dopant sensitivity data, e.g., domain knowledge data for a change in the threshold voltage according to a change in doping concentration, may be applied to the machine learning model 200c. As described above with reference to FIG. 11, from the dose sensitivity data obtained empirically from a lot of accumulated process data, the machine learning model 200c may, when the doping concentration and/or dopant profile is changed by a certain amount, obtain information about the degree of change of the threshold voltage value accordingly. Accordingly, the machine learning model 200c may compute the third loss L_{Phy} obtained by comparing the output value of the machine learning model 200c with the actual measurement value (dose sensitivity data) and may be trained by utilizing the third loss L_{Phy} as a loss term of the loss function. As a result, the machine learning model 200c may be trained to converge to the domain knowledge data.

In some example embodiments, the machine learning model 200c trained based on the method described above may be utilized in a targeting process. For example, to satisfy the target specification, some of conditions of sub process steps, defined as input data, may be adjusted. For example, to satisfy the specification corresponding to the center of the targeting box TB as described above, the doping concentration of the NFET and/or PFET may vary. The machine learning model 200c may predict the changed characteristics (for example, a change in the threshold voltage) of the semiconductor device in response to the change in the doping concentration, and accordingly, the result may be illustrated as a second targeting graph targeting graph 2. As illustrated in the second targeting graph targeting graph 2, the specification of the semiconductor device may be implemented as a second point p2, and located at the center of the targeting box TB, and accordingly, the center targeting may be successful.

For example, as described above with reference to FIGS. 10 to 12, the machine learning model 200c may predict a change in the characteristics of the semiconductor device by reflecting the change in the physical characteristics of the semiconductor processes in real time, and based on the prediction, may provide information for an interpretation/analysis.

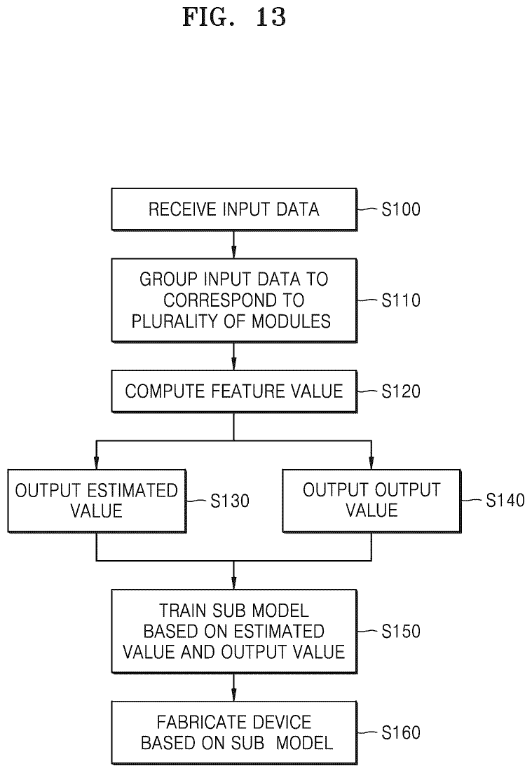

FIG. 13 is a flowchart of a modeling method according to some example embodiments.

Referring to FIG. 13, the modeling method according to various example embodiments may include a plurality of steps or operations S100, S110, S120, S130, S140, S150, and S160 as shown therein. Hereinafter, FIG. 13 is described with reference to the previous diagrams, and duplicate descriptions given with reference to the previous diagrams are omitted.

In operation S100, the machine learning model 200 may receive input data. The input data may be data defining the process steps and measurement steps. The process steps may include sub process steps for manufacturing a semiconductor device, and the measurement steps may include steps for identifying whether the sub process steps have been performed properly.

In operation S110, the input data may be classified to correspond to the plurality of modules through grouping. The sub process steps may be classified to correspond to the plurality of modules based on the measurement steps. For example, the input data may be divided based on the measurement steps, and the sub process steps performed between the measurement steps may be grouped to correspond to one module. Accordingly, the plurality of modules may respectively correspond to the measurement steps.

In operation S120, the machine learning model 200 may represent data for the sub process steps as feature values (for example, by performing the filtering process described above). For example, data for each of the sub process steps may be output as a feature value fv via the convolution layer 20, and as a result, sequentiality between the sub process steps may also be reflected.

In operation S130, the machine learning model 200 may output feature values predicting result values of the measurement steps. The machine learning model 200 may output an estimated value corresponding to each of the plurality of modules (that is, for each module) by performing various computations based on the feature value. In other words, the estimated value may be a value for predicting a result of sub process steps included in each module. In some example embodiments, the machine learning model 200 may include a sub model, which computes an estimated value based on the feature values, and the sub model may include a fully connected layer.

In operation S140, the machine learning model 200 may output values related to prediction of characteristics of a semiconductor device based on the feature value. In some example embodiments, the machine learning model 200 may include a sub model, which computes an output value based on the feature values, and the sub model may include one or more fully connected layers.

In operation S150, the machine learning model 200 may be trained based on an estimated value and an output value. For example, the machine learning model 200 may train the sub model by comparing the estimated value and the output value, which are estimated values of the machine learning model 200, with the actual measurement values (or accumulated measurement values).

Some example embodiments may fabricate a device based on the output of the machine learning model 200; however, example embodiments are not limited thereto. For example, in operation S160, a semiconductor device may be fabricated based on the sub model. For example, the semiconductor device may be doped or implanted with impurities based on the sub model.

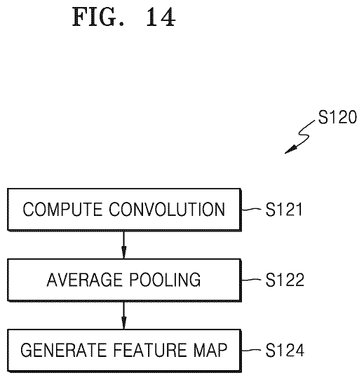

FIG. 14 is a flowchart of a feature value fv calculation method according to some example embodiments.

Referring to FIGS. 13 and 14, the modeling method according to various example embodiments may compute a feature value based on various methods and may generate a feature map based on the feature value. Operation S120 of computing the feature value may include a plurality of operations S121, S122, and S124. Hereinafter, FIG. 14 is described mainly with reference to FIGS. 5 to 7, and duplicate descriptions given with reference to the previous diagrams are omitted.

In operation S121, the machine learning model 200 may perform convolution computation for performing a certain filtering operation. The machine learning model 200 may represent the sub process steps grouped to correspond to the plurality of modules based on the convolution computation as particular value(s) (for example, feature value(s)). Sequentiality between sub process steps may be reflected in data through the filtering process. For example, the machine learning model 200 may include a convolution layer. The machine learning model 200 may input data for sub process steps to the convolution layer, based on the plurality of modules, and may output computation result values.

In some example embodiments, in operation S122, the machine learning model 200 may output a feature value based on the result values of the convolution computation. The machine learning model 200 may compute an average of the result values step conv by performing an average pooling operation. For example, the machine learning model 200 may include the average pooling layer. The machine learning model 200 may input the result values of the convolution computation to the average pooling layer and output the feature values.

In some example embodiments, in operation S124, the machine learning model 200 may generate a feature map based on the feature value. The machine learning model 200 may match each of the sub process steps with the feature values corresponding thereto and express the result in the form of a graph. Based on the graph, a correlation between the sub process step and the characteristics of a semiconductor device may be identified.

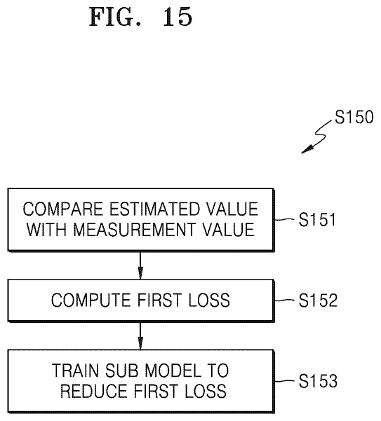

FIG. 15 is a flowchart of a training method according to some example embodiments.

Referring to FIGS. 9 and 15, the modeling method according to various example embodiments may perform training based on the estimated value. The machine learning model 200 may be trained by comparing the estimated value with the actual measurement value.

In operation S151, the machine learning model 200 may compare the estimated values corresponding to each of the plurality of modules with the actual measurement values. The actual measurement value may be the actual measurement result of each of the measurement steps and accordingly, may correspond to each of the plurality of modules. The machine learning model 200 may obtain (or receive) the estimated value and compare the obtained estimated value with the measurement value corresponding thereto. In other words, the machine learning model 200 may compute and compare estimated values with each other for each module.

In operation S152, the machine learning model 200 may compute the first loss L_{Met} that is obtained by comparing the estimated value with the measurement value. For example, the machine learning model 200 may output the first loss L_{Met} obtained by summing the differences between each of a plurality of estimated values and each of the measurement values.

In operation S153, the machine learning model 200 may utilize the first loss L_{Met} as an input to various loss functions, and may be trained so that the estimated value approaches the measurement value. In some example embodiments, a sub model of the machine learning model 200, which computes the estimated value based on the feature values, may be trained. For example, the machine learning model 200 may adjust the weights and/or biases between the nodes of the first fully connected layer for computing the estimated value. Accordingly, the machine learning model 200 may be trained for each module.

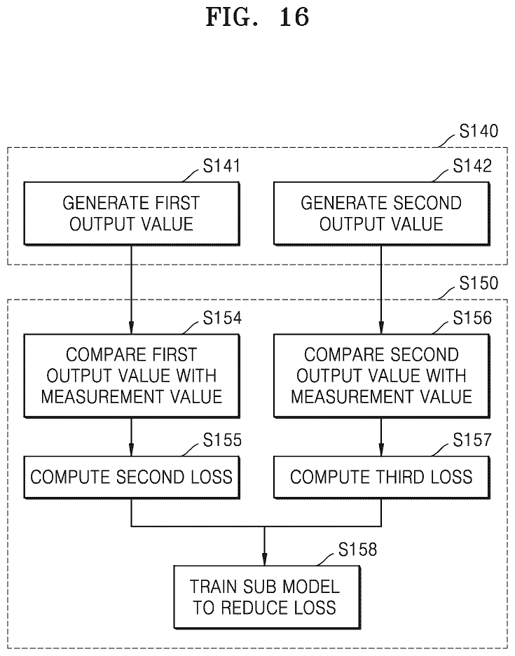

FIG. 16 is a flowchart of a training method according to some example embodiments.

Referring to FIGS. 10, 11, and 16, the modeling method according to various example embodiments may perform training based on the output value of a model.

In operation S141, the machine learning model 200 may generate a first output value for predicting the characteristics of a semiconductor device to be manufactured by using sub process steps included in the input data. In some example embodiments, the machine learning model 200 may include a sub model computing the first output value based on the feature values. For example, the machine learning model 200 may predict the threshold voltage value of a particular transistor included in a semiconductor device to be manufactured.

In operation S154, the machine learning model 200 may compare the first output value with the actual measurement value. The machine learning model 200 may compare the predicted value (first output value) thereof with a value (measurement value) indicating the characteristics of the semiconductor device actually manufactured according to process steps defined in the input data.

In operation S155, the machine learning model 200 may compute the second loss L_{ET} that is the result of comparing the first output value with the actual measurement value. For example, the machine learning model 200 may output the difference between the predicted threshold voltage value and the threshold voltage value of the actually manufactured semiconductor device as the second loss L_{ET}.

In operation S142, the machine learning model 200 may generate a second output value predicting change of the characteristics of the semiconductor device according to change of the physical characteristics. In some example embodiments, the machine learning model 200 may include a sub model computing the second output value based on the feature values. For example, the machine learning model 200 may compute the amount of change of the threshold voltage and/or some other electrical property such as on-current of a particular transistor according to a change of the doping concentration and/or a change of a profile of dopants.

In operation S156, the machine learning model 200 may compare the second output value with the actual measurement value. The machine learning model 200 may compare the predicted value (the second output value) thereof with a value (measurement value) indicating the amount of change of the characteristics of the semiconductor device that actually occurs, according to the change of the physical characteristics of a semiconductor processes. For example, the measurement value may be data obtained empirically from numerous accumulated processes. In various example embodiments, the machine learning model 200 may obtain (or receive), as the measurement value, the amount of the change in the characteristics of the semiconductor device corresponding to a change in the physical characteristics (for example, doping concentration, structure, pressure, or the like) of a semiconductor processes to be identified from the database (for example, domain knowledge data) that synthesizes numerous accumulated semiconductor process results.

In operation S157, the machine learning model 200 may compute the third loss L_{Phy} that is a result of comparing the second output value with the actual measurement value (for example, domain knowledge data). For example, the machine learning model 200 may output, as the third loss L_{Phy}, the difference between the amount of change of the predicted threshold voltage and the amount of change of the actually measured threshold voltage value of the semiconductor device (for example, obtained from the domain knowledge data).

In operation S158, the machine learning model 200 may be trained so that the predicted value of the machine learning model 200 approaches the measurement value by utilizing the second loss L_{Met} and/or the third loss L_{Phy} as inputs of various loss functions. In some example embodiments, a sub model of the machine learning model 200, which computes the first output value and the second output value based on the feature values, may be trained. For example, the machine learning model 200a may adjust the weights and/or biases between the nodes of the first fully connected layer for computing the second output value and/or a third output value.

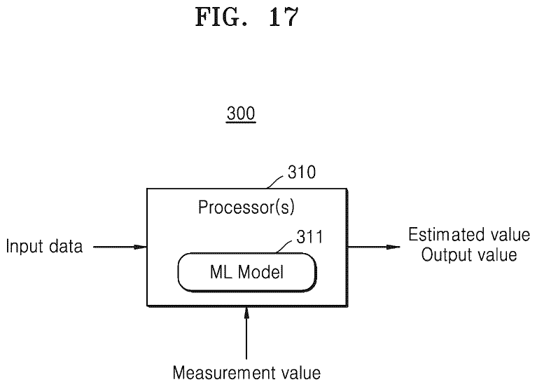

FIG. 17 is a block diagram of a process of providing a machine learning model 311, according to some example embodiments.

Referring to FIGS. 1 and 17, at least one processor(s) 310 may provide the machine learning model 311 for modeling a semiconductor process. The machine learning model 311 may correspond to the machine learning model 200 in FIG. 1. Hereinafter, FIG. 17 is described with reference to the previous diagrams, and duplicate descriptions given with reference to the previous diagrams are omitted.

The at least one processor(s) 310 may execute a program module including a system executable command. The program module may include routines, programs, objects, components, logic, data structures, and/or the like that perform a particular task or implement a particular abstract data type. For example, at least one processor(s) 310 may include any one or more of a central processing unit (CPU), a graphics processing unit (GPU), and a neural processing unit (NPU). However, this is an example, and the at least one processor(s) 310 is not limited thereto. The at least one processor(s) 310 may receive the input data defining the sub process steps and the measurement steps. The at least one processor(s) 310 may divide the process steps included in the input data into the plurality of modules based on the modularization described above. The at least one processor(s) 310 may execute the machine learning model 311 to output an estimated value and/or an output value representing the characteristics of the semiconductor device. In addition, the at least one processor 310 may receive a measurement value obtained from an actually measured value and a database obtained by performing a process to train the machine learning model 311.

In some example embodiments, the machine learning model 311 may include an ANN and/or an algorithm to performing a modeling operation on a semiconductor process. The machine learning model 311 may output the estimated value based on the input data. The estimated value may be or may correspond to a value for predicting the result of measurement steps, and the machine learning model 311 may predict a result of performing sub process steps included in one module and may output the estimated value. The machine learning model 311 may output an output value for predicting the characteristics of a semiconductor device based on the input data. The output value may include a value for predicting a change in the characteristics of the semiconductor device according to the change in the physical characteristics.

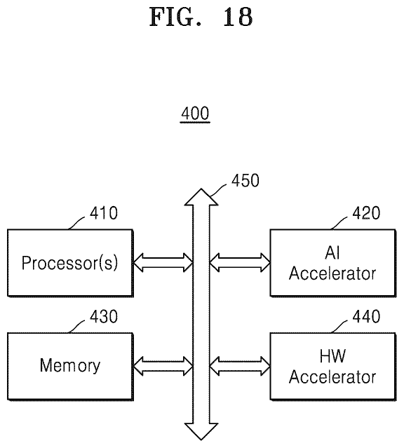

FIG. 18 is a block diagram of a modeling system 400 according to some example embodiments.

Referring to FIGS. 17 and 18, the modeling system 400 of a semiconductor process may include at least one processor(s) 410, an artificial intelligence (AI) accelerator 420, a memory 430, and a hardware accelerator 440, and the at least one processor(s) 410, the AI accelerator 420, the memory 430, and the hardware accelerator 440 may communicate with each other via a bus 450. The at least one processor(s) 410 may correspond to the at least one processor(s) 310 in FIG. 17. In some example embodiments, the at least one processor(s) 410, the AI accelerator 420, the memory 430, and the hardware accelerator 440 may also be included in one semiconductor chip. In addition, in some example embodiments, at least two of the at least one processor(s) 410, the AI accelerator 420, the memory 430, and the hardware accelerator 440 may also be included in each of two or more semiconductor chips mounted on a board.

The at least one processor(s) 410 may execute commands. For example, the at least one processor(s) 410 may also execute an operating system by executing commands stored in the memory 430, and/or may execute applications executed on the operating system. In some example embodiments, the at least one processor(s) 410 may instruct tasks to the AI accelerator 420 and/or the hardware accelerator 440 by executing commands, and may also obtain a result of performing the tasks from the AI accelerator 420 and/or the hardware accelerator 440. In some example embodiments, the at least one processor(s) 410 may include an application specific instruction set processor (ASIP) customized for a particular usage, and may also support a dedicated instruction set.

The memory 430 may have an arbitrary structure for storing data. For example, the memory 430 may also or alternatively include a volatile memory device, such as one or more of dynamic random access memory (RAM) (DRAM), static RAM (SRAM), or may include a non-volatile memory device, such as flash memory and resistive RAM (RRAM). The at least one processor(s) 410, the AI accelerator 420, and the hardware accelerator 440 may store data (for example, the input data, the measurement value, the estimated value, and the output value in FIG. 1) in the memory 430 via the bus 450, or may read data (for example, the input data, the measurement value, the estimated value, and the output value in FIG. 1) from the memory 430.

The AI accelerator 420 may be referred to as hardware designed for AI applications. In some example embodiments, the AI accelerator 420 may include an NPU for implementing a neuromorphic structure, may generate output data by processing input data provided by the at least one processor(s) 410 and/or the hardware accelerator 440, and may provide the output data to the at least one processor(s) 410 and/or the hardware accelerator 440. In some example embodiments, the AI accelerator 420 may be programmable, and may be programmed by the at least one processor(s) 410 and/or the hardware accelerator 440.

The hardware accelerator 440 may be referred to as hardware designed to perform a particular task at a high speed. For example, the hardware accelerator 440 may be designed to perform data transformation at a high speed, such as demodulation, modulation, encoding, and decoding. The hardware accelerator 440 may be programmable, and may be programmed by the at least one processor(s) 410 and/or the hardware accelerator 440.

In some example embodiments, the AI accelerator 420 may execute the machine learning models (for example, the machine learning model 200 of FIG. 2) described above with reference to the previous diagrams. Alternatively or additionally, for example, the AI accelerator 420 may execute a model outputting the feature values based on the input data described above and a model predicting the estimated value for each of the plurality of modules or predicting the characteristics of a semiconductor device. The AI accelerator 420 may generate an output including useful information by processing input parameters, the feature map, etc. In addition, in some example embodiments, at least some of the models executed by the AI accelerator 420 may also be executed by the at least one processor(s) 410 and/or the hardware accelerator 440.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various example embodiments have been particularly shown and described with reference to various example embodiments thereof, it will be understood that various change in form and details may be made therein without departing from the spirit and scope of the following claims. Example embodiments are not necessarily mutually exclusive. For example, some example embodiments may include one or more features described with reference to one or more figures and may also include one or more other features described with reference to one or more other figures.

1. A method of modeling a semiconductor process, the method comprising:
obtaining a measurement value based on input data defining sub process steps and measurement steps;
based on the measurement steps, grouping the sub process steps to respectively correspond to a plurality of modules; and
based on the grouped sub process steps, training a machine learning model to predict at least one characteristic of a semiconductor device,
wherein the machine learning model comprises,
a first sub model configured to output at least one feature value based on the plurality of modules, and
a second sub model, based on the at least one feature value, configured to output an output value representing an estimated value corresponding to each of the plurality of modules and the at least one characteristic of the semiconductor device.

2. (canceled)

3. The method of claim 1, wherein the first sub model comprises a convolution layer configured to receive the plurality of modules.

4. The method of claim 3, wherein the first sub model outputs a value based on an average of output values of the convolution layer corresponding to each of the sub process steps as the feature value.

5. The method of claim 1, wherein the first sub model, based on the feature value, generates a feature map corresponding to each of the sub process steps.

6. The method of claim 1,
wherein the second sub model comprises a first fully connected layer configured to output the estimated value,
the measurement value comprises a first measurement value, the first measurement value being a result of performing each of the measurement steps, and
the training of the machine learning model comprises,
training to reduce a first loss obtained by comparing the estimated value and the first measurement value.

7. The method of claim 1, wherein the output value comprises:
a first output value predicting the at least one characteristic of the semiconductor device; and
a second output value predicting an amount of change of the at least one characteristic of the semiconductor device according to change of at least one physical characteristic of the semiconductor process, wherein
the second sub model comprises a second fully connected layer configured to output the output value.

8. The method of claim 7, wherein
the measurement value comprises a second measurement value obtained by actually measuring the at least one characteristic of the semiconductor device, and
the training of the machine learning model comprises training to reduce a second loss obtained by comparing the first output value and the second measurement value.

9. The method of claim 7, wherein
the measurement value comprises a third measurement value obtained by actually measuring change of the at least one characteristic of the semiconductor device, and
the training of the machine learning model comprises training to reduce a third loss obtained by comparing the second output value and the third measurement value.

10. The method of claim 7, wherein
the at least one physical characteristic represents doping concentration, and
the amount of change of the characteristic represents an amount of change in at least one electrical characteristic of the semiconductor device.

11. (canceled)

12. A method of modeling a semiconductor process, the method comprising:
receiving input data defining sub process steps and measurement steps;
based on the measurement steps, grouping the sub process steps to correspond to a plurality of modules;
computing at least one feature value corresponding to each of the sub process steps;
by using a sub model, outputting an estimated value corresponding to each of the plurality of modules based on the feature value;
by using the sub model, outputting an output value representing at least one characteristic of a semiconductor device based on the feature value; and
based on at least one of the estimated value and the output value, training the sub model.

13. (canceled)

14. The method of claim 12, wherein the computing of the feature value comprises performing convolution computation on each of the plurality of modules.

15. (canceled)

16. (canceled)

17. The method of claim 12, wherein
the outputting of the estimated value comprises computing a first loss obtained by comparing the estimated value with an actual measurement value of each of the measurement steps, and
the training of the sub model comprises training the sub model to reduce the first loss.

18. The method of claim 12, wherein the output value comprises:
the first output value predicting the at least one characteristic of the semiconductor device; and
a second output value predicting an amount of change of the characteristic of the semiconductor device according to change of at least one physical characteristic.

19. (canceled)

20. The method of claim 18, wherein
The outputting of the output value comprises comparing the second output value with an actually measured amount of change of the at least one characteristic of the semiconductor device to compute a third loss, and
the training of the sub model comprises training the sub model to reduce the third loss.

21. (canceled)

22. A system for modeling a semiconductor process, the system comprising:
at least one processor configured to execute machine-readable instructions that, when executed by the at least one processor, cause the system receive input data defining sub process steps and measurement steps and provide a machine learning model configured to predict at least one characteristic of a semiconductor device based on the input data,
wherein the machine learning model is configured to compute a feature value corresponding to each of the sub process steps, and
based on the feature value, to output a first output value predicting at least one characteristic of a semiconductor device and a second output value predicting an amount of change of the at least one characteristic of the semiconductor device according to change of at least one physical characteristic.

23. The system of claim 22, wherein the at least one processor,
based on the measurement steps, is configured to group the sub process steps to correspond to a plurality of modules, and
to compute an estimated value corresponding to each of the plurality of modules.

24. (canceled)

25. The system of claim 22, wherein the machine learning model is configured to perform at least one convolution computation on each of the sub process steps.

26. (canceled)

27. (canceled)

28. The system of claim 23, wherein the at least one processor
is configured to receive a first measurement value based on a performance result of the measurement steps, and
to train the machine learning model so that a first loss obtained by comparing the estimated value with the first measurement value is reduced.

29. (canceled)

30. The system of claim 22, wherein the at least one processor
is configured to receive a third measurement value based on an actually measured amount of change of characteristic of the semiconductor device, and
is configured to train the machine learning model so that a third loss obtained by comparing the second output value with the third measurement value is reduced.

31. The system of claim 22, wherein
the at least one physical characteristic represents doping concentration, and
the amount of change represents an amount of change in at least one electrical characteristic of the semiconductor device.
